(19) United States
(12) Patent Application Publication
(10) Pub. No.: US 2026/0020479 A1
(43) Pub. Date: Jan. 15, 2026

(54) DISPLAY DEVICE, METHOD FOR MANUFACTURING THE SAME, AND ELECTRONIC DEVICE INCLUDING THE SAME

(71) Applicant: Samsung Display Co., Ltd., Yongin-si (KR)

(72) Inventors: KI NYENG KANG, Yongin-si (KR); SUNGEUN LEE, Yongin-si (KR); EONJOO LEE, Yongin-si (KR); KEUNKYU SONG, Yongin-si (KR)

(21) Appl. No.: 19/203,495

(22) Filed: May 9, 2025

(30) Foreign Application Priority Data
Jul. 10, 2024 (KR) 10-2024-0091314

(51) Int. Cl. H10K 59/80; H10K 59/12; H10K 59/40

(52) U.S. Cl. CPC H10K 59/873; H10K 59/1201; H10K 59/40

(57) ABSTRACT

A display device includes: a light-emitting element including a pixel electrode, a light-emitting layer, and a common electrode sequentially on a substrate; an encapsulation layer located on the light-emitting element; a first touch insulating layer located on the encapsulation layer; a first touch electrode located on the first touch insulating layer; a second touch insulating layer covering the first touch electrode on the first touch insulating layer, including a first portion overlapping the light-emitting layer in a plan view and a second portion spaced from the first portion with a trench therebetween, and having an undercut shape by the trench; an organic layer located on the second touch insulating layer and defining an opening overlapping the light-emitting layer in the plan view; and a planarization layer disposed on the organic layer.

### CROSS-REFERENCE TO RELATED APPLICATION

The present application claims priority to and benefit of Korean Patent Application No. 10-2024-0091314, filed on Jul. 10, 2024, in the Korean Intellectual Property Office, the entire content of which is incorporated herein by reference.

### BACKGROUND

### 1. Field

One or more embodiments of the present disclosure relate to a display device. For example, one or more embodiments of present disclosure relate to a display device which provides visual information and a method for manufacturing the same.

### 2. Description of the Related Art

As information technology progresses, display devices, which are communication media between users and information, are becoming essential. Accordingly, the use of display devices such as a liquid crystal display device, an organic light emitting display device, a plasma display device, and/or the like is increasing.

### SUMMARY

One or more aspects of embodiments of the present disclosure are directed toward a display device having (with) improved reliability.

One or more aspects of embodiments of the present disclosure are directed toward a method for manufacturing the display device.

One or more aspects of embodiments of the present disclosure are directed toward an electronic device including the display device.

Additional aspects will be set forth in part in the description which follows and, in part, will be apparent from the description, or may be learned by practice of the presented embodiments.

According to one or more embodiments of the present disclosure, a display device includes: a light-emitting element including a pixel electrode, a light-emitting layer, and a common electrode sequentially on a substrate; an encapsulation layer on (e.g., located on) the light-emitting element; a first touch insulating layer on (e.g., located on) the encapsulation layer; a first touch electrode on (e.g., located on) the first touch insulating layer; a second touch insulating layer covering the first touch electrode on the first touch insulating layer, including a first portion overlapping the light-emitting layer in a plan view and a second portion spaced and/or apart (e.g., spaced apart or separated) from the first portion with a trench therebetween, and having an undercut shape by the trench; an organic layer on (e.g., located on) the second touch insulating layer and defining an opening overlapping the light-emitting layer in the plan view; and a planarization layer on (e.g., arranged on) the organic layer.

In one or more embodiments, the trench may include a first sub-trench exposing at least a portion of the first touch insulating layer and having a first width and a second sub-trench exposing the first sub-trench and having a second width smaller than the first width.

In one or more embodiments, a first side surface of each of the first and second portions of the second touch insulating layer defining the first sub-trench may have an inverse tapered shape, and a second side surface of each of the first and second portions of the second touch insulating layer defining the second sub-trench may have a tapered shape.

In one or more embodiments, the display device may further include a residual metal layer under (e.g., located under) a protrusion portion included in the second touch insulating layer which protrudes toward a center of the trench.

In one or more embodiments, the first touch electrode may include a lower conductive layer including transparent conductive oxide containing indium (In) and an upper conductive layer on (e.g., located on) the lower conductive layer and including a metal.

In one or more embodiments, an etch rate of the upper conductive layer may be greater than an etch rate of the lower conductive layer for a same etchant, and the etch rate of the lower conductive layer may be greater than an etch rate of the first touch insulating layer for a same etchant.

In one or more embodiments, the upper conductive layer may have a multilayer structure.

In one or more embodiments, the upper conductive layer may have a multilayer structure including titanium (Ti) and aluminum (Al) (e.g., including a titanium layer and an aluminum layer).

In one or more embodiments, a portion of the first touch insulating layer exposed by the trench may have a substantially flat upper surface.

In one or more embodiments, the display device may further include a second touch electrode on (e.g., located on) the second touch insulating layer and connected to the first touch electrode through a contact hole penetrating the second touch insulating layer.

In one or more embodiments, the first touch insulating layer and the second touch insulating layer may include an inorganic insulating material.

In one or more embodiments, each of the first touch insulating layer and the second touch insulating layer may have a first refractive index, the organic layer may have a second refractive index smaller than the first refractive index, and the planarization layer may have a third refractive index smaller than the first refractive index.

In one or more embodiments, the third refractive index may be greater than the second refractive index.

In one or more embodiments, the organic layer may entirely cover the trench and directly contact an upper surface of the first touch insulating layer through the trench.

In one or more embodiments, the display device may further include a light-blocking layer on (e.g., located on) the second touch insulating layer and defining an opening overlapping the light-emitting layer in the plan view, a color filter layer on (e.g., located on) the second touch insulating layer and the light-blocking layer, and an overcoat layer between (e.g., located between) the color filter layer and the organic layer.

In one or more embodiments, the light-blocking layer may cover at least a portion of the trench and directly contact an upper surface of the first touch insulating layer through the trench.

A method for manufacturing a display device according to one or more embodiments of the present disclosure is provided, the method includes: forming a light-emitting element including a pixel electrode, a light-emitting layer, and a common electrode on a substrate: forming an encapsulation layer on the light-emitting element, forming a first touch insulating layer on the encapsulation layer; forming a first touch electrode including a lower conductive layer containing transparent conductive oxide and an upper conductive layer including a metal on the lower conductive layer, while concurrently (e.g., simultaneously) forming an etch stop layer including a lower etch stop layer including a same material as the lower conductive layer and an upper etch stop layer including a same material as the upper conductive layer on the lower etch stop layer on the first touch insulating layer; forming a preliminary second touch insulating layer covering the first touch electrode and the etch stop layer on the first touch insulating layer; forming a second touch insulating layer exposing at least a portion of each of the first touch electrode and the upper etch stop layer by removing a portion of the preliminary second touch insulating layer, removing the upper etch stop layer through a first etching process, removing the lower etch stop layer through a second etching process; forming an organic layer defined an opening overlapping the light-emitting layer in a plan view on the second touch insulating layer; and forming a planarization layer on the organic layer.

In one or more embodiments, in the first etching process, an etch rate of the upper etch stop layer may be greater than an etch rate of the lower etch stop layer.

In one or more embodiments, in the second etching process, an etch rate of the lower etch stop layer may be greater than an etch rate of the first touch insulating layer.

In one or more embodiments, the first etching process may be a dry etching process and the second etching process may be a wet etching process.

In one or more embodiments, each of the lower conductive layer and the lower etch stop layer may include a transparent conductive oxide containing indium.

In one or more embodiments, each of the upper conductive layer and the upper etch stop layer may have a multilayer structure including titanium and aluminum (e.g., including a titanium layer and an aluminum layer).

In one or more embodiments, the second touch insulating layer may include a first portion overlapping the light-emitting layer in the plan view and a second portion spaced and/or apart (e.g., spaced apart or separated) from the first portion with the etch stop layer therebetween. After the removing the lower etch stop layer, a trench may be formed in the second touch insulating layer exposing at least a portion of the first touch insulating layer in an area where the etch stop layer is removed, and the second touch insulating layer has an undercut shape by the trench.

In one or more embodiments, after the forming the second touch insulating layer, a second sub-trench exposing at least a portion of the lower etch stop layer and having a second width may be formed in the second touch insulating layer. After the removing the lower etch stop layer, a first sub-trench exposing at least a portion of the first touch insulating layer, having a first width greater the second width, and exposed by the second sub-trench may be formed in the second touch insulating layer. The trench may include the first sub-trench and the second sub-trench.

In one or more embodiments, the first sub-trench may be formed in a space where the etch stop layer is removed.

In one or more embodiments, the first touch insulating layer and the second touch insulating layer may each include an inorganic insulating material.

According to one or more embodiments of the present disclosure, an electronic device includes a display device and a processor which transfers image data signal and input control signal to the display device, the display device includes: a light-emitting element including a pixel electrode, a light-emitting layer, and a common electrode sequentially on a substrate; an encapsulation layer on (e.g., located on) the light-emitting element; a first touch insulating layer on (e.g., located on) the encapsulation layer; a first touch electrode on (e.g., located on) the first touch insulating layer; a second touch insulating layer covering the first touch electrode on the first touch insulating layer, including a first portion overlapping the light-emitting layer in a plan view and a second portion spaced and/or apart (e.g., spaced apart or separated) from the first portion with a trench therebetween, and having an undercut shape by the trench; an organic layer on (e.g., located on) the second touch insulating layer and defining an opening overlapping the light-emitting layer in the plan view; and a planarization layer on (e.g., arranged on) the organic layer.

In the display device according to one or more embodiments of the present disclosure, a trench around (e.g., surrounding) a light-emitting layer in a plan view is defined in a second touch insulating layer, and an opening overlapping the light-emitting layer in the plan view may be defined in an organic layer located on the second touch insulating layer. Consequently, a front efficiency of the display device may be improved.

In a method for manufacturing the display device according to one or more embodiments of the present disclosure, an etch stop layer including a lower etch stop layer and an upper etch stop layer may be formed through substantially the same process as forming a first touch electrode. The etch stop layer may be removed through an etching process. In this regard, an etch rate of the upper etch stop layer is greater than an etch rate of the lower etch stop layer for a same etchant, and the etch rate of the lower etch stop layer may be greater than an etch rate of a first touch insulating layer located under the second touch insulating layer for a same etchant.

As a result, after a trench is formed in the second touch insulating layer by removing the etch stop layer, a portion of the first touch insulating layer exposed by the trench may have a substantially uniform thickness, and a second inorganic encapsulation layer may not be damaged. In addition, a pixel shrinkage phenomenon, in which a light-emitting area is reduced due to damage to the second inorganic encapsulation layer, may be suppressed or reduced.

### BRIEF DESCRIPTION OF DRAWINGS

Illustrative, non-limiting embodiments will be more clearly understood from the following detailed description in conjunction with the accompanying drawings; however, they may be embodied in different forms and should not be construed as limited to example embodiments set forth herein. Rather, these embodiments are provided so that this disclosure will be thorough and complete, and will fully convey the scope of the example embodiments to those skilled in the art. The above and other aspects, features, and advantages of certain embodiments of the present disclosure will be more apparent from the following description taken in conjunction with the accompanying drawings.

FIG. 1 is a plan view showing a display device according to one or more embodiments of the present disclosure.

FIG. 2 is an equivalent circuit diagram showing one pixel of FIG. 1 according to one or more embodiments of the present disclosure.

FIG. 3 is an enlarged plan view of area A of FIG. 1 according to one or more embodiments of the present disclosure.

FIG. 4 is a plan view showing a portion of FIG. 3 according to one or more embodiments of the present disclosure.

FIG. 5 is a cross-sectional view taken along the line I-I′ of FIG. 4 according to one or more embodiments of the present disclosure.

FIG. 6 is an enlarged cross-sectional view of area B of FIG. 5 according to one or more embodiments of the present disclosure.

FIGS. 7, 8, 9, 10, 11, 12, 13, 14, and 15 are cross-sectional views for explaining a method for manufacturing the display device of FIG. 5 according to one or more embodiments of the present disclosure.

FIG. 16 is a cross-sectional view showing a display device according to one or more embodiments of the present disclosure.

FIG. 17 is a plan view showing the display device of FIG. 16 according to one or more embodiments of the present disclosure.

FIG. 18 is a block diagram showing an electronic device according to one or more embodiments of the present disclosure.

FIG. 19 are schematic diagrams showing an electronic device according to one or more suitable embodiments of the present disclosure.

### DETAILED DESCRIPTION

Hereinafter, a display device, a method for manufacturing the same, and an electronic device including the same according to one or more embodiments of the present disclosure will be explained in more detail with reference to the accompanying drawings. The same reference numerals are used for the same components in the drawings, and redundant descriptions of the same components will not be provided for conciseness.

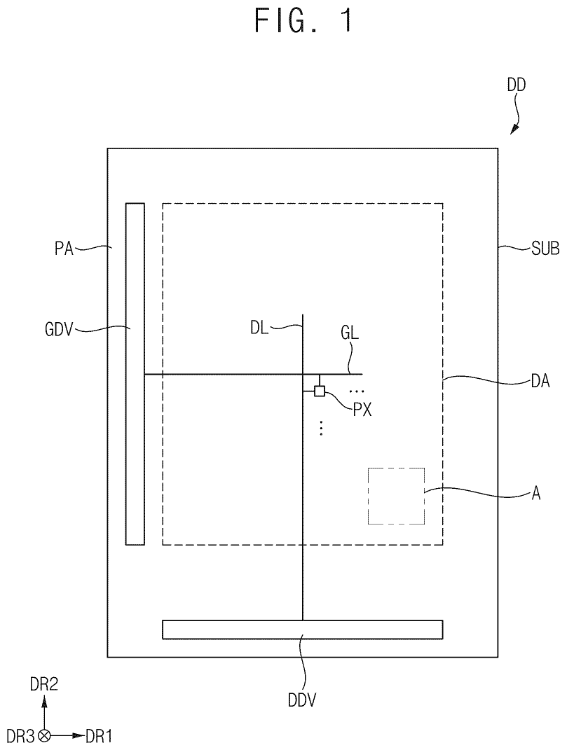

FIG. 1 is a plan view showing a display device according to one or more embodiments of the present disclosure.

Referring to FIG. 1, a display device DD according to one or more embodiments of the present disclosure may include a substrate SUB, a plurality of pixels PX, a data line DL, a gate line GL, a gate driver GDV, and a data driver DDV.

The substrate SUB may include a display area DA and a peripheral area PA. The display area DA may be an area that may display an image by generating light or adjusting the transmittance of light provided from an external light source. The peripheral area PA may be an area that does not display images. The peripheral area PA may be located around the display area DA. For example, in one or more embodiments, the peripheral area PA may entirely be around (e.g., surround) the display area DA.

A plurality of pixels PX may be arranged (or located) in the display area DA on the substrate SUB. The plurality of pixels PX may be arranged in a matrix form along a first direction DR1 and a second direction DR2 crossing the first direction DR1.

Each of the plurality of pixels PX may include a driving element (e.g., a driving thin film transistor) which generates a driving current, and a light-emitting element which is electrically connected to the driving element and generates light based on the driving current. Accordingly, each of the plurality of pixels PX may be to emit light according to the driving current.

Drivers for driving each of the plurality of pixels PX may be arranged (or located) in the peripheral area PA on the substrate SUB. For example, the drivers may include the gate driver GDV and the data driver DDV.

The gate line GL may be electrically connected to the gate driver GDV and may extend along, for example, the first direction DR1. The gate line GL may receive a gate signal from the gate driver GDV and transmit the gate signal to the plurality of pixels PX.

The data line DL may be electrically connected to the data driver DDV and may extend along, for example, the second direction DR2. The data line DL may receive a data voltage from the data driver DDV and transmit the data voltage to the plurality of pixels PX.

For example, in one or more embodiments, as shown in FIG. 1, the data driver DDV may be arranged (or located) directly on the substrate SUB. In one or more embodiments, the data driver DDV may be arranged (or located) on a circuit board (e.g., a printed circuit board (PCB) or flexible printed circuit board (FPCB)) electrically connected to a pad electrode arranged (or located) in one side of the peripheral area PA.

In this disclosure, a plane may be defined by the first direction DR1 and the second direction DR2 crossing the first direction DR1. For example, the first direction DR1 and the second direction DR2 may be normal (e.g., perpendicular) to each other. In addition, a third direction DR3 may be normal (e.g., perpendicular) to the plane.

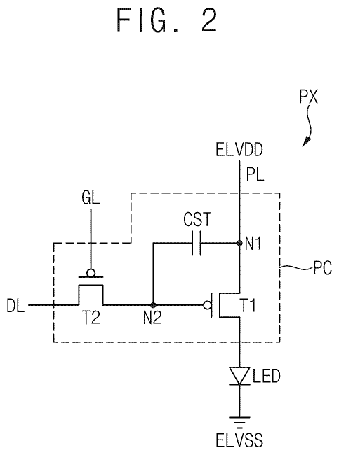

FIG. 2 is an equivalent circuit diagram showing one pixel of FIG. 1 according to one or more embodiments of the present disclosure.

Referring to FIG. 2, a (e.g., one) pixel PX may include a pixel circuit PC and a light-emitting element LED electrically connected to the pixel circuit PC. The pixel circuit PC may generate a driving current, and the light-emitting element LED may generate light based on the driving current.

For example, the pixel circuit PC may include a first transistor T1, a second transistor T2, and a storage capacitor CST.

The first transistor T1 may include a first electrode, a second electrode, and a gate electrode. The first electrode of the first transistor T1 may be connected to a first node N1 connected to a driving voltage line PL. The first electrode of the first transistor T1 may receive a driving voltage ELVDD through the driving voltage line PL. The second electrode of the first transistor T1 may be connected to an anode electrode of the light-emitting element LED. The gate electrode of the first transistor T1 may be connected to a second node N2.

The first transistor T1 may receive the driving voltage ELVDD corresponding to the voltage of the second node N2 and supply the driving current to the light-emitting element LED. The first transistor T1 may be a driving transistor for driving the light-emitting element LED.

The second transistor T2 may include a first electrode, a second electrode, and a gate electrode. The first electrode of the second transistor T2 may be connected to the data line DL. The first electrode of the second transistor T2 may receive a data voltage through the data line DL. The second electrode of the second transistor T2 may be connected to the second node N2. The gate electrode of the second transistor T2 may be connected to the gate line GL. The gate electrode of the second transistor T2 may receive a gate signal through the gate line GL.

The second transistor T2 may be turned on by the gate signal to provide the data voltage to the second node N2.

For example, in one or more embodiments, each of the first transistor T1 and the second transistor T2 may be a p-channel metal-oxide-semiconductor (PMOS) transistor. However, embodiments of the present disclosure are not necessarily limited thereto. In one or more embodiments, at least one of the first transistor T1 or the second transistor T2 may be a n-channel metal-oxide-semiconductor (NMOS) transistor.

For example, in one or more embodiments, the first electrode of each of the first transistor T1 and the second transistor T2 may be a source electrode, and the second electrode of each of the first transistor T1 and the second transistor T2 may be a drain electrode. However, embodiments of the present disclosure are not necessarily limited thereto. In one or more embodiments, the first electrode of each of the first transistor T1 and the second transistor T2 may be a drain electrode, and the second electrode of each of the first transistor T1 and second transistor T2 may be a source electrode.

The storage capacitor CST may include a first electrode and a second electrode. The first electrode of the storage capacitor CST may be connected to the first node N1. The second electrode of the storage capacitor CST may be connected to the second node N2. The storage capacitor CST may store the difference voltage between the gate voltage and the source voltage of the first transistor T1.

The light-emitting element LED may include an anode electrode and a cathode electrode. The anode electrode of the light-emitting element LED may be connected to the second electrode of the first transistor T1. A common voltage ELVSS may be applied to the cathode electrode of the light-emitting element LED.

FIG. 2 illustrates that the pixel circuit PC includes two transistors and one capacitor, but embodiments of the present disclosure are not necessarily limited thereto. The number of transistors and the number of capacitors may vary depending on the design of the pixel circuit PC.

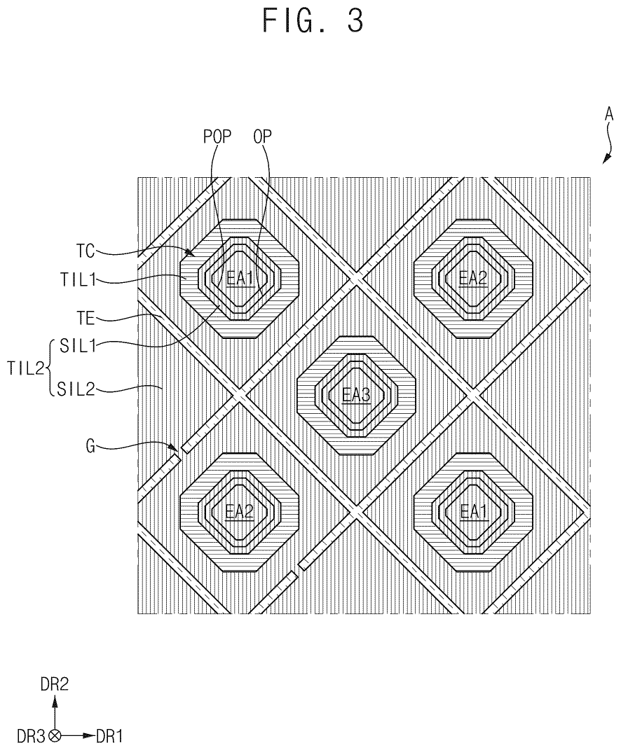

FIG. 3 is an enlarged plan view of area A of FIG. 1 according to one or more embodiments of the present disclosure.

Referring to FIG. 1 and FIG. 3, the display area DA may include a first light-emitting area EA1, a second light-emitting area EA2, and a third light-emitting area EA3. For example, in one or more embodiments, the first light-emitting area EA1 may be to emit red light (or blue light), the second light-emitting area EA2 may be to emit blue light (or red light), and the third light-emitting area EA3 may be to emit green light. The pixels PX are elements which emit light, and each of the pixels PX may include the first, second, and third light-emitting areas EA1, EA2, and EA3.

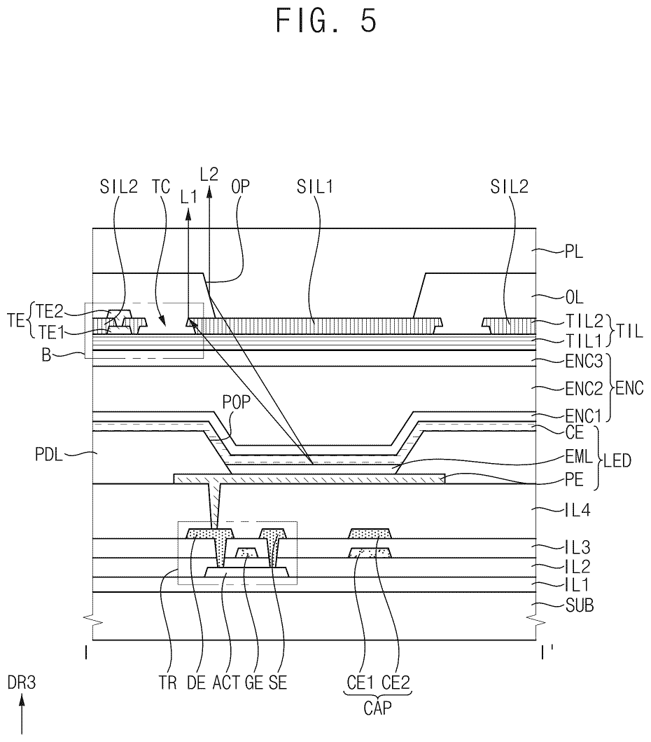

The first, second, and third light-emitting areas EA1, EA2, and EA3 may be each defined by a pixel opening POP of a pixel defining layer (e.g., a pixel defining layer PDL of FIG. 5). For example, a size (or width) of the pixel opening POP may correspond to a size (or width) of each of the first, second, and third light-emitting areas EA1, EA2, and EA3. For example, in one or more embodiments, each of the first, second, and third light-emitting areas EA1, EA2, and EA3 may correspond to a size (or width) of the pixel.

In one or more embodiments, the display device DD may include a touch structure which detects a user's touch. The touch structure may include a touch insulating layer TIL and a touch electrode TE. (Referring to FIGS. 3 to 5)

In one or more embodiments, the touch electrode TE may have a mesh structure in a plan view. For example, the touch electrode TE has a mesh structure formed by crossing first sub-portions extending along a first diagonal direction and second sub-portions extending along a second diagonal direction crossing the first diagonal direction. Here, the first diagonal direction may be a direction between the first direction DR1 and the second direction DR2, and the second diagonal direction may be a direction between the first direction DR1 and a direction opposite to the second direction DR2.

The touch electrode TE may at least partially be around (e.g., surround) each of the first, second, and third light-emitting areas EA1, EA2, and EA3 in the plan view. For example, in one or more embodiments, some of the first, second, and third light-emitting areas EA1, EA2, and EA3 may be each entirely surrounded by the touch electrode TE. In these embodiments, a gap G may be defined in the touch electrode TE, and other portions of the first, second, and third light-emitting areas EA1, EA2, and EA3 may be partially surrounded by the touch electrode TE.

The touch insulating layer TIL may include a first touch insulating layer TIL1 and a second touch insulating layer TIL2. The first touch insulating layer TIL1 may be arranged (or located) under the touch electrode TE, and the second touch insulating layer TIL2 may be arranged (or located) on the touch electrode TE. In one or more embodiments, a trench TC may be defined in the second touch insulating layer TIL2 to be around (e.g., surround) each of the first, second, and third light-emitting areas EA1, EA2, and EA3 in the plan view. The second touch insulating layer TIL2 may include a first portion SIL1 overlapping each of the first, second, and third light-emitting areas EA1, EA2, and EA3 and a second portion SIL2 spaced and/or apart (e.g., spaced apart or separated) from the first portion SIL1 with the trench TC therebetween. For example, the first portion SIL1 of the second touch insulating layer TIL2 may have an isolated shape.

An organic layer (e.g., an organic layer OL of FIG. 5) may be arranged (or located) on the touch insulating layer TIL. The organic layer may cover at least a portion of the trench TC. In one or more embodiments, the organic layer may entirely cover the second portion SIL2 and the trench TC, and may cover a portion of the first portion SIL1. However, embodiments of the present disclosure are not necessarily limited thereto. An opening OP overlapping each of the first, second, and third light-emitting areas EA1, EA2, and EA3 and the first portion SIL1 may be defined in the organic layer in the plan view. Unless defined otherwise, a “plan view” refers to a view showing the layout and arrangement of components on a flat plane. In this context, the flat plan is defined by the first direction DR1 and the second direction DR2, providing a top-down view of the touch electrode TE and its relationship to the light-emitting areas EA1, EA2, and EA3.

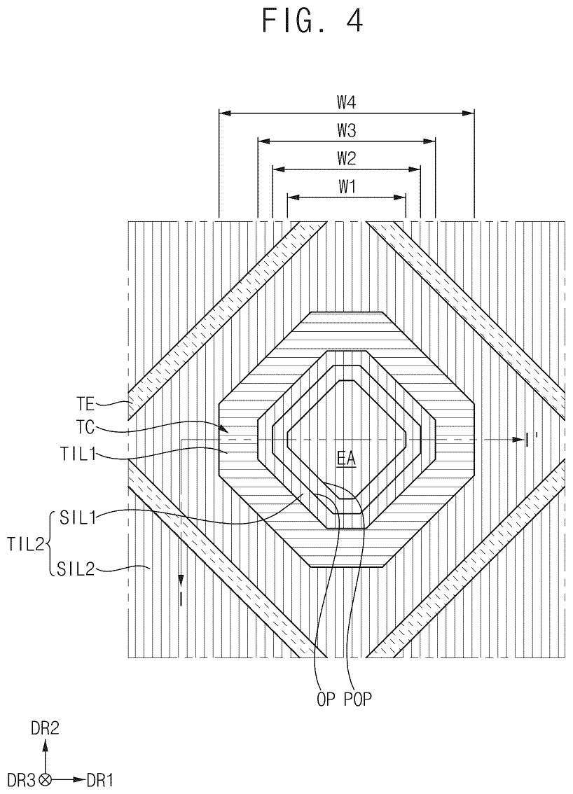

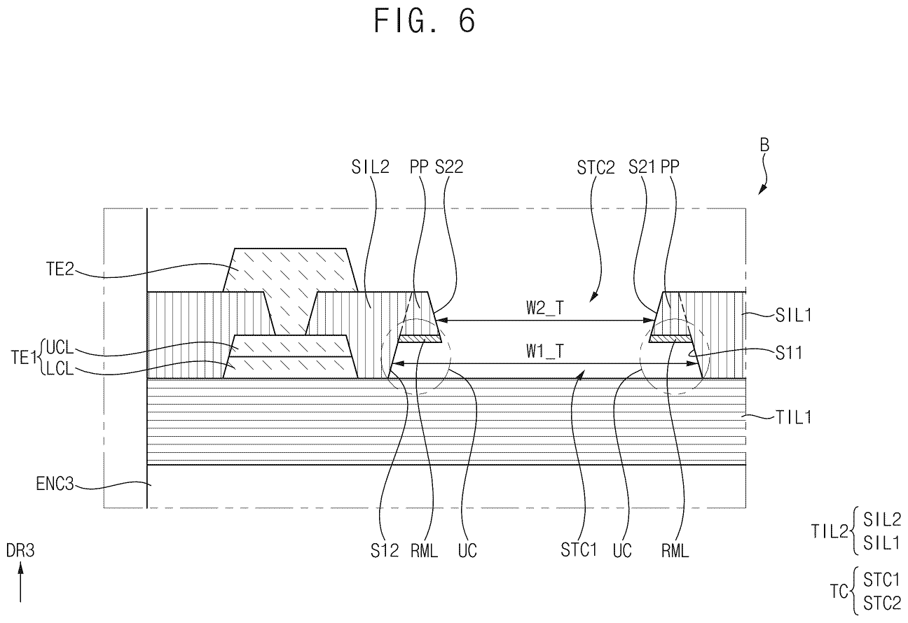

FIG. 4 is a plan view showing a portion of FIG. 3 according to one or more embodiments of the present disclosure. FIG. 5 is a cross-sectional view taken along the line I-I′ of FIG. 4 according to one or more embodiments of the present disclosure. FIG. 6 is an enlarged cross-sectional view of area B of FIG. 5 according to one or more embodiments of the present disclosure.

Referring to FIGS. 4, 5, and 6, in one or more embodiments, the display device DD may include a substrate SUB, a transistor TR, a capacitor CAP, first, second, third, and fourth insulating layers IL1, IL2, IL3, and IL4, the light-emitting element LED, the pixel defining layer PDL, an encapsulation layer ENC, the touch structure, the organic layer OL, and a planarization layer PL.

Here, the transistor TR may include an active pattern ACT, a gate electrode GE, a source electrode SE, and a drain electrode DE, and the capacitor CAP may include a first electrode CE1 and a second electrode CE2. In addition, the light-emitting element LED may include a pixel electrode PE, a light-emitting layer EML, and a common electrode CE.

The substrate SUB may include a transparent material or an opaque material. In one or more embodiments, the substrate SUB may be made of a transparent resin substrate. Non-limiting examples of the transparent resin substrate may include a polyimide substrate. For example, the polyimide substrate may include a first organic layer, a first barrier layer, a second organic layer, and/or the like. In one or more embodiments, the substrate SUB may include a quartz substrate, a synthetic quartz substrate, a calcium fluoride substrate, an F-doped quartz substrate, a soda-lime glass substrate, a non-alkali glass substrate, and/or the like. These may be used alone or in combination with each other.

The first insulating layer IL1 may be arranged (or located) on the substrate SUB. The first insulating layer IL1 may prevent or reduce metal atoms and/or impurities from diffusing from the substrate SUB to the transistor TR. In addition, the first insulating layer IL1 may improve the flatness of the surface of the substrate SUB if (e.g., when) the surface of the substrate SUB is not substantially uniform. For example, in one or more embodiments, the first insulating layer IL1 may include an inorganic material such as silicon oxide (SiOₓ), silicon nitride (SiNₓ), silicon oxynitride (SiOₓN_{y}), and/or the like. These may be used alone or in combination with each other.

The active pattern ACT may be arranged (or located) on the first insulating layer IL1. In one or more embodiments, the active pattern ACT may include a metal oxide semiconductor, an inorganic semiconductor (e.g., amorphous silicon, poly silicon), or an organic semiconductor.

The metal oxide semiconductor may include a binary compound (ABx), a ternary compound (ABxCy), a quaternary compound (ABxCyDz), and/or the like containing indium (In), zinc (Zn), gallium (Ga), tin (Sn), titanium (Ti), aluminum (AI), hafnium (Hf), zirconium (Zr), magnesium (Mg), and/or the like. For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), indium gallium zinc oxide (IGZO), and/or the like. These can be used alone or in combination with each other.

The active pattern ACT may include a source region, a drain region, and a channel region located between the source region and the drain region. For example, the source region and the drain region may be doped with impurities, i.e., as a dopant, (e.g., P-type (kind) impurities or N-type (kind) impurities), and the channel region may not be doped with impurities.

The second insulating layer IL2 may be arranged (or located) on the first insulating layer IL1. In one or more embodiments, the second insulating layer IL2 may sufficiently cover the active pattern ACT and may have a substantially flat upper surface without creating a step around the active pattern ACT. In one or more embodiments, the second insulating layer IL2 may cover the active pattern ACT and may be arranged along the profile of the active pattern ACT with a substantially uniform thickness. For example, the second insulating layer IL2 may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and/or the like. These may be used alone or in combination with each other.

The gate electrode GE may be arranged (or located) on the second insulating layer IL2. The gate electrode GE may overlap the channel region of the active pattern ACT. The gate electrode GE may include a metal, an alloy, a metal nitride, a conductive metal oxide, a transparent conductive material, and/or the like. Non-limiting examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and/or the like. Non-limiting examples of the conductive metal oxide may include indium tin oxide, indium zinc oxide, and/or the like. In addition, non-limiting examples of the metal nitride may include aluminum nitride (AlNₓ), tungsten nitride (WNₓ), chromium nitride (CrNₓ), and/or the like. These may be used alone or in combination with each other.

The first electrode CE1 may be arranged (or located) on the second insulating layer IL2. The first electrode CE1 may be arranged (or located) in substantially the same layer as the gate electrode GE. For example, the first electrode CE1 may include the same material as the gate electrode GE and may be formed through substantially the same process as the gate electrode GE.

The third insulating layer IL3 may be arranged (or located) on the second insulating layer IL2. In one or more embodiments, the third insulating layer IL3 may sufficiently cover the gate electrode GE and the first electrode CE1, and may have a substantially flat upper surface without creating steps around the gate electrode GE and the first electrode CE1. In one or more embodiments, the third insulating layer IL3 may cover the gate electrode GE and the first electrode CE1 and may be arranged along the profile of each of the gate electrode GE and the first electrode CE1 with a substantially uniform thickness. For example, the third insulating layer IL3 may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and/or the like. These may be used alone or in combination with each other.

The source electrode SE and the drain electrode DE may be arranged on the third insulating layer IL3. The source electrode SE may be connected to the source region of the active pattern ACT through a contact hole penetrating the second and third insulating layers IL2 and IL3. The drain electrode DE may be connected to the drain region of the active pattern ACT through a contact hole penetrating the second and third insulating layers IL2 and IL3. For example, each of the source electrode SE and the drain electrode DE may include a metal, an alloy, a metal nitride, a conductive metal oxide, a transparent conductive material, and/or the like. These may be used alone or in combination with each other.

Accordingly, the transistor TR including the active pattern ACT, the gate electrode GE, the source electrode SE, and the drain electrode DE may be formed. The transistor TR may correspond to the first transistor T1 of FIG. 2.

The second electrode CE2 may be arranged (or located) on the third insulating layer IL3. The second electrode CE2 may overlap the first electrode CE1 in the plan view. The second electrode CE2 may be arranged (or located) in substantially the same layer as the source electrode SE and the drain electrode DE. For example, the second electrode CE2 may include the same material as the source electrode SE and the drain electrode DE, and may be formed through substantially the same process as the source electrode SE and the drain electrode DE. The second electrode CE2 may form the capacitor CAP together with the first electrode CE1. The capacitor CAP may correspond to the storage capacitor CST of FIG. 2.

The fourth insulating layer IL4 may be arranged on the third insulating layer IL3. The fourth insulating layer IL4 may sufficiently cover the source electrode SE, the drain electrode DE, and the second electrode CE2. For example, the fourth insulating layer IL4 may have a substantially flat upper surface. For example, the fourth insulating layer IL4 may include an organic material such as a photoresist, a polyacrylic resin, a polyimide resin, a polyamide resin, a siloxane resin, an acrylic resin, an epoxy resin, and/or the like. These may be used alone or in combination with each other.

The pixel electrode PE may be arranged on the fourth insulating layer IL4. The pixel electrode PE may be connected to the drain electrode DE (or the source electrode SE) through a contact hole penetrating the fourth insulating layer IL4. For example, each of the pixel electrodes PE may function as an anode electrode of the light-emitting element LED.

The pixel electrode PE may include a reflective electrode. For example, the pixel electrode PE may include a metal, an alloy, a metal nitride, a conductive metal oxide, a transparent conductive material, and/or the like. These may be used alone or in combination with each other. In one or more embodiments, the pixel electrode PE may have a three-layer structure including ITO/Ag/ITO. However, embodiments of the present disclosure are not necessarily limited thereto.

The pixel defining layer PDL may be arranged on the fourth insulating layer IL4 and the pixel electrode PE. A pixel opening POP exposing at least a portion of an upper surface of the pixel electrode PE may be defined in the pixel defining layer PDL. The pixel defining layer PDL may include organic and/or inorganic materials. In one or more embodiments, the pixel defining layer PDL may include an organic material. For example, the pixel defining layer PDL may include a photoresist, a polyacrylic resin, a polyimide resin, a polyamide resin, a siloxane resin, an acrylic resin, an epoxy resin, and/or the like. These may be used alone or in combination with each other.

The light-emitting layer EML may be arranged (or located) on the pixel electrode PE. For example, the light-emitting layer EML may be arranged (or located) inside the pixel opening POP of the pixel defining layer PDL. The light-emitting layer EML may include a light emitting material which is to emit set or predetermined light. For example, in one or more embodiments, the light-emitting layer EML may include a high molecular weight organic material or a low molecular weight organic material. However, embodiments of the present disclosure are not necessarily limited thereto.

A hole transport layer and/or a hole injection layer may be further arranged (or located) between the pixel electrode PE and the light-emitting layer EML. In addition, an electron transport layer and/or an electron injection layer may be further arranged between the light-emitting layer EML and the common electrode CE.

The common electrode CE may be arranged (or located) on the pixel defining layer PDL and the light-emitting layer EML. The common electrode CE may be arranged (or located) on an entire surface of the display area DA. In one or more embodiments, the common electrode CE may include a semi-transmissive electrode or a transmissive electrode. The common electrode CE may include a conductive material with a low work function.

Accordingly, the light-emitting element LED including the pixel electrode PE, the light-emitting layer EML, and the common electrode CE may be formed. The light-emitting element LED may be electrically connected to the transistor TR. A light-emitting area EA may be defined by the pixel opening POP of the pixel defining layer PDL. For example, a width W1 of the pixel opening POP may correspond to a width of the light-emitting area EA. The light-emitting area EA of FIG. 4 may correspond to any one of (e.g., any one selected from among) the first, second, and third light-emitting areas EA1, EA2, and EA3 of FIG. 3.

The encapsulation layer ENC may be arranged (or located) on the common electrode CE. The encapsulation layer ENC may prevent or reduce impurities, moisture, and/or the like from penetrating into the light-emitting element LED from the outside. In one or more embodiments, the encapsulation layer ENC may include at least one inorganic encapsulation layer and at least one organic encapsulation layer. For example, the encapsulation layer ENC may include a first inorganic encapsulation layer ENC1 arranged (or located) on the common electrode CE, a second inorganic encapsulation layer ENC3 arranged (or located) on the first inorganic encapsulation layer ENC1, and an organic encapsulation layer ENC2 arranged (or located) between the first inorganic encapsulation layer ENC1 and the second inorganic encapsulation layer ENC3.

The touch structure may be arranged (or located) on the encapsulation layer ENC. As described above, the touch structure may include the first touch insulating layer TIL1, the touch electrode TE, and the second touch insulating layer TIL2. The touch electrode TE may include a first touch electrode TE1 and a second touch electrode TE2.

First, the first touch insulating layer TIL1 may be arranged (or located) on the encapsulation layer ENC. The first touch insulating layer TIL1 may be arranged (or located) on a front surface of the display area DA. For example, the first touch insulating layer TIL1 may be arranged as a common layer in the display area DA. The first touch insulating layer TIL1 may include an inorganic insulating material. For example, in one or more embodiments, the first touch insulating layer TIL1 may include an inorganic insulating material such as silicon oxide, silicon nitride, silicon oxynitride, and/or the like. These may be used alone or in combination with each other.

The first touch electrode TE1 may be arranged (or located) on the first touch insulating layer TIL1. In one or more embodiments, the first touch electrode TE1 may include a lower conductive layer LCL and an upper conductive layer UCL arranged (or located) on the lower conductive layer LCL. For example, the first touch electrode TE1 may have a multilayer structure.

The lower conductive layer LCL may include a transparent conductive oxide. In one or more embodiments, the lower conductive layer LCL may include a transparent conductive oxide containing indium (In). For example, in one or more embodiments, the lower conductive layer LCL may include indium gallium oxide (IGO), indium zinc oxide (IZO), indium tin oxide (ITO), indium zinc tin oxide (IZTO), indium gallium zinc oxide (IGZO), and/or the like. These may be used alone or in combination with each other. However, embodiments of the present disclosure are not necessarily limited thereto. The lower conductive layer LCL may have a single-layer structure or a multi-layer structure.

The upper conductive layer UCL may include a metal, an alloy, and/or the like. For example, in one or more embodiments, the upper conductive layer UCL may include titanium (Ti), aluminum (AI), copper (Cu), molybdenum (Mo), and/or the like. These may be used alone or in combination with each other. The upper conductive layer UCL may have a single-layer structure or a multi-layer structure. In one or more embodiments, the upper conductive layer UCL may have a multilayer structure including a first layer containing titanium, a second layer containing aluminum, and a third layer containing titanium. However, embodiments of the present disclosure are not necessarily limited thereto.

In one or more embodiments, the etch rate of the upper conductive layer UCL may be greater than the etch rate of the lower conductive layer LCL for a same etchant, and the etch rate of the lower conductive layer LCL may be greater than the etch rate of the first touch insulating layer TIL1 for a same etchant. For example, the upper conductive layer UCL may include a material with a higher etch selectivity than the lower conductive layer LCL, and the lower conductive layer LCL may include a material with a higher etch selectivity than the first touch insulating layer TIL1.

The second touch insulating layer TIL2 may be arranged (or located) on the first touch insulating layer TIL1. The second touch insulating layer TIL2 may cover the first touch electrode TE1. In one or more embodiments, as described above, the trench TC may be defined in the second touch insulating layer TIL2 to be entirely around (e.g., surround) the light-emitting area EA (i.e., the light-emitting layer EML) in the plan view. In addition, the second touch insulating layer TIL2 may include the first portion SIL1 overlapping the light-emitting area EA (i.e., the light-emitting layer EML) and the second portion SIL2 spaced and/or apart (e.g., spaced apart or separated) from the first portion SIL1 with the trench TC therebetween.

A distance between an outer edge of the first portion SIL1 and an inner edge of the second portion SIL2 may correspond to a width of the trench TC. For example, in one or more embodiments, the distance may be ½ the difference between a width W4 between the inner edges of the second portion SIL2 and a width W3 of the first portion SIL1. However, embodiments of the present disclosure are not necessarily limited thereto.

As shown in FIG. 5 and FIG. 6, the trench TC may have the shape of a through hole, and accordingly, a depth of the trench TC may be substantially the same as a thickness of the second touch insulating layer TIL2.

The trench TC may expose at least a portion of the first touch insulating layer TIL1. In one or more embodiments, a portion of the first touch insulating layer TIL1 exposed by the trench TC may have a substantially flat upper surface. For example, the portion of the first touch insulating layer TIL1 exposed by the trench TC may have a substantially uniform thickness.

The second touch insulating layer TIL2 may include an inorganic insulating material. For example, in one or more embodiments, the second touch insulating layer TIL2 may include an inorganic insulating material such as silicon oxide, silicon nitride, silicon oxynitride, and/or the like. These may be used alone or in combination with each other.

For example, in one or more embodiments, the second touch insulating layer TIL2 may include an inorganic insulating material different from an inorganic insulating material of the first touch insulating layer TIL1. In one or more embodiments, the second touch insulating layer TIL2 may include the same inorganic insulating material as the first touch insulating layer TIL1.

In one or more embodiments, the second touch insulating layer TIL2 may have an undercut shape UC by the trench TC. For example, as an upper portion of the second touch insulating layer TIL2 includes a protrusion portion PP protruding toward a center of the trench TC, the second touch insulating layer TIL2 may have the undercut shape UC by the trench TC.

For example, the trench TC may include a first sub-trench STC1 having a first width W1_T exposing at least a portion of the first touch insulating layer TIL1 and a second sub-trench STC2 having a second width W2_T exposing the first sub-trench STC1. Here, the second width W2_T may be smaller than the first width W1_T.

In addition, the first portion SIL1 of the second touch insulating layer TIL2 may have a first side surface S11 defining the first sub-trench STC1 and a second side surface S21 defining the second sub-trench STC2. The second portion SIL2 of the second touch insulating layer TIL2 may have a first side surface S12 defining the first sub-trench STC1 and a second side surface S22 defining the second sub-trench STC2. Because the second width W2_T is smaller than the first width W1_T, the second side surfaces S21 and S22 may protrude more toward the center of the trench TC than the first side surfaces S11 and S12.

As a result, the second touch insulating layer TIL2 may have the undercut shape UC by the trench TC including the first and second sub-trenches STC1 and STC2.

In one or more embodiments, each of the first side surfaces S11 and S12 of the first and second portions SIL1 and SIL2 of the second touch insulating layer TIL2 may have an inverse tapered shape, and each of the second side surfaces S21 and S22 of the first and second portions SIL1 and SIL2 of the second touch insulating layer TIL2 may have a tapered shape. In other words, each of the first side surface S11 of the first portion SIL1 and the first side surface S12 of the second portion SIL2 of the second touch insulating layer TIL2 may have an inverse tapered shape, while each of the second side surface S21 of the first portion SIL1 and the second side surface S22 of the second portion SIL2 of the second touch insulating layer TIL2 may have a tapered shape. An “inverse tapered” shape refers to that the width between the side surfaces (e.g., S11 and S12) decreases as it moves away from the base (bottom), creating a narrower top compared to the bottom. This is the opposite of a regular tapered shape, where the width between the side surfaces (e.g., S21 and S22) increases as it moves away from the base (bottom), resulting in a wider top compared to the bottom.

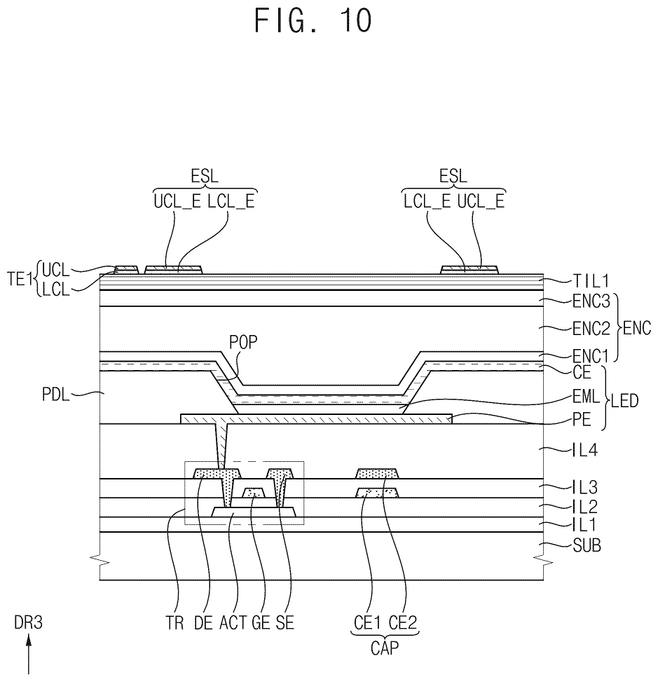

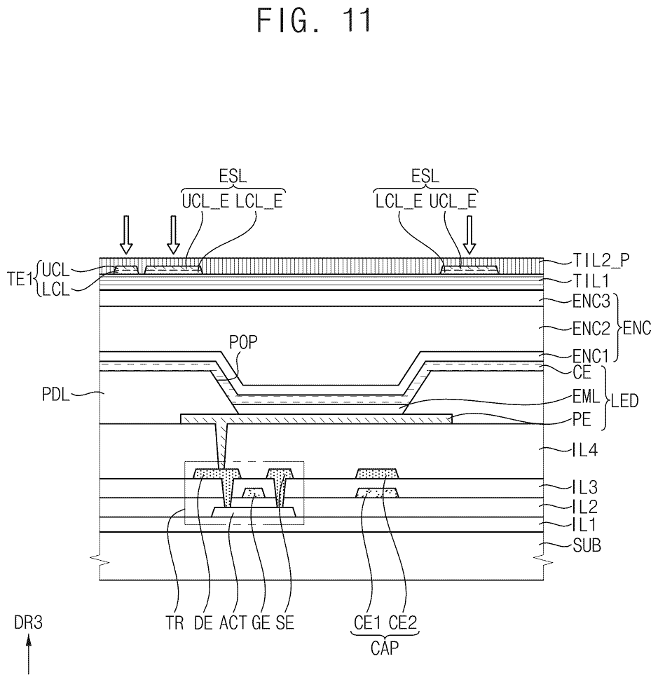

In one or more embodiments, a residual metal layer RML may be arranged (or located) under the protrusion portion PP of the second touch insulating layer TIL2. For example, the residual metal layer RML may be arranged (or located) at the edge of the first sub-trench STC1. When the upper conductive layer UCL of the first touch electrode TE1 has a multilayer structure, the residual metal layer RML may be formed through substantially the same process as a partial layer (e.g., a layer including titanium) of the upper conductive layer UCL. For example, in one or more embodiments, the residual metal layer RML may be a layer formed by remaining a partial layer (e.g., a layer including titanium) of an etch stop layer (e.g., an etch stop layer ESL of FIG. 10) to be described in more detail later without being removed. However, embodiments of the present disclosure are not necessarily limited to this, and the residual metal layer RML may not remain after an etching process.

The second touch electrode TE2 may be arranged (or located) on the second touch insulating layer TIL2. The second touch electrode TE2 may be connected to the first touch electrode TE1 through a contact hole penetrating the second touch insulating layer TIL2. For example, the second touch electrode TE2 may include a metal, an alloy, a metal nitride, a conductive metal oxide, a transparent conductive material, and/or the like. These may be used alone or in combination with each other.

The organic layer OL may be arranged (or located) on the second touch insulating layer TIL2. The organic layer OL may cover the touch electrode TE and may protect the touch electrode TE. An opening OP may be defined in the organic layer OL. The opening OP may overlap the light-emitting area EA (i.e., the light-emitting layer EML), the pixel opening POP, and the first portion SIL1 of the second touch insulating layer TIL2 in the plan view. In FIG. 5, the opening OP may expose at least a portion of the second touch insulating layer TIL2.

For example, in one or more embodiments, a width W2 of the opening OP may be greater than a width W1 of the pixel opening POP. In one or more embodiments, the width W2 of the opening OP may be substantially same as the width W1 of the pixel opening POP. In addition, the width W2 of the opening OP may be smaller than a width W3 of the first portion SIL1. In one or more embodiments, the width W2 of the opening OP may be substantially same as the width W3 of the first portion SIL1. However, embodiments of the present disclosure are not necessarily limited thereto.

As described above, the organic layer OL may entirely cover the second portion SIL2 and the trench TC, and may cover a portion of the first portion SIL1. The organic layer OL may be directly contact the first side surfaces S11 and S12 and the second side surfaces S21 and S22 of the first and second portions SIL1 and SIL2 defining the trench TC. In addition, the organic layer OL may directly contact an upper surface of the first touch insulating layer TIL1 through the trench TC. In one or more embodiments, a side surface of the organic layer OL defining the opening OP may have a tapered shape.

For example, in one or more embodiments, the organic layer OL may include an organic insulating material such as an acrylic resin, an epoxy resin, a polyimide resin, a polyethylene resin, and/or the like. In one or more embodiments, the organic layer OL may further include a photocurable material.

The planarization layer PL may be arranged (or located) on the organic layer OL. The planarization layer PL may have a substantially flat upper surface. The planarization layer PL may fill the opening OP. The planarization layer PL may directly contact an upper surface of the first portion SIL1 of the second touch insulating layer TIL2 through the opening OP.

For example, in one or more embodiments, the planarization layer PL may include an organic insulating material such as an acrylic resin, an epoxy resin, a polyimide resin, a polyethylene resin, and/or the like. In one or more embodiments, in the planarization layer PL, dispersed particles (e.g., metal oxide particles such as zinc oxide (ZnOₓ), titanium oxide (TiO₂), zirconium oxide (ZrO₂), and/or the like) for high refractive index may be dispersed in the above-mentioned organic insulating material.

The refractive indices of the touch insulating layer TIL, the organic layer OL, and the planarization layer PL may be different from each other. In one or more embodiments, the touch insulating layer TIL may have a first refractive index, the organic layer OL may have a second refractive index that is smaller than the first refractive index, and the planarization layer PL may have a third refractive index that is smaller than the first refractive index. In these embodiments, the third refractive index may be greater than the second refractive index.

For example, in one or more embodiments, the first refractive index may be from about 1.8 to about 2.0, the second refractive index may be from about 1.3 to about 1.6, and the third refractive index may be from about 1.6 to about 1.8. In one or more embodiments, the first refractive index may be from about 1.8 to about 1.9, the second refractive index may be from about 1.5, and the third refractive index may be from about 1.6 to about 1.7. However, embodiments of the present disclosure are not necessarily limited thereto.

Due to the difference in structure and refractive index of the touch insulating layer TIL and the organic layer OL, a first light L1 among light emitted from the light-emitting layer EML may travel in a direction oblique to the third direction DR3 and may be refracted at the side surface of the first portion SIL1 of the touch insulating layer TIL and travel along the third direction DR3 (i.e., a direction normal (e.g., perpendicular) to the substrate SUB). Accordingly, the front efficiency of the display device DD may be improved.

Light may also be refracted at the side surface of the organic layer OL defining the opening OP. Due to the difference in structure and refractive index of the organic layer OL and the planarization layer PL, a second light L2 among the light emitted from the light-emitting layer EML may travel in a direction oblique to the third direction DR3 and may be refracted at the side surface of the organic layer OL defining the opening OP and travel along the third direction DR3 (i.e., a direction normal (e.g., perpendicular) to the substrate SUB). Accordingly, the front efficiency of the display device DD may be improved.

As a result, as the trench TC around (e.g., surrounding) the light-emitting layer EML is defined in the second touch insulating layer TIL2 in the plan view, and the opening OP overlapping the light-emitting layer EML in the plan view is defined in the organic layer OL, the front efficiency of the display device DD may be improved.

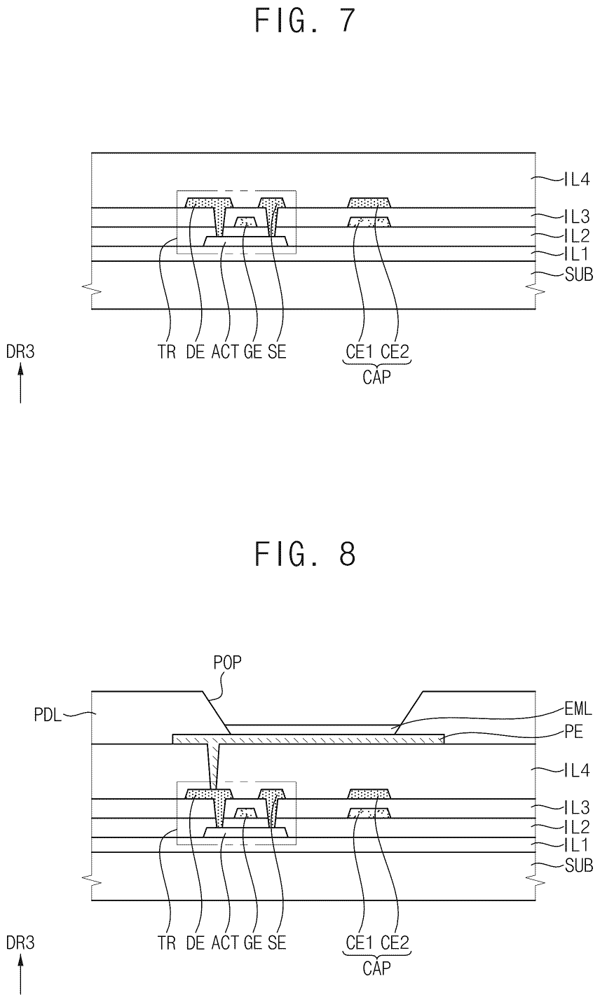

FIGS. 7, 8, 9, 10, 11, 12, 13, 14, and 15 are cross-sectional views for explaining a method for manufacturing the display device of FIG. 5.

Referring to FIG. 7, the first insulating layer IL1, the active pattern ACT, the second insulating layer IL2, the gate electrode GE, the first electrode CE1, the third insulating layer IL3, the source electrode SE, the drain electrode DE, the second electrode CE2, and the fourth insulating layer IL4 may be sequentially formed on the substrate SUB.

Accordingly, the transistor TR including the active pattern ACT, the gate electrode GE, the source electrode SE, and the drain electrode DE may be formed, and the capacitor CAP including the first electrode CE1 and the second electrode CE2 may be formed.

Referring to FIG. 8, the pixel electrode PE may be formed on the fourth insulating layer IL4. The pixel electrode PE may be connected to the drain electrode DE through a contact hole where a portion of the fourth insulating layer IL4 is removed.

The pixel defining layer PDL may be formed on the fourth insulating layer IL4. The pixel opening POP exposing at least a portion of the pixel electrode PE may be defined in the pixel defining layer PDL. For example, after a preliminary pixel defining layer is entirely formed on the fourth insulating layer IL4, the preliminary pixel defining layer may be patterned to form the pixel defining layer PDL defining the pixel opening POP.

The light-emitting layer EML may be formed inside the pixel opening POP. For example, the light-emitting layer EML may be formed using a low-molecular organic material or a high-molecular organic material.

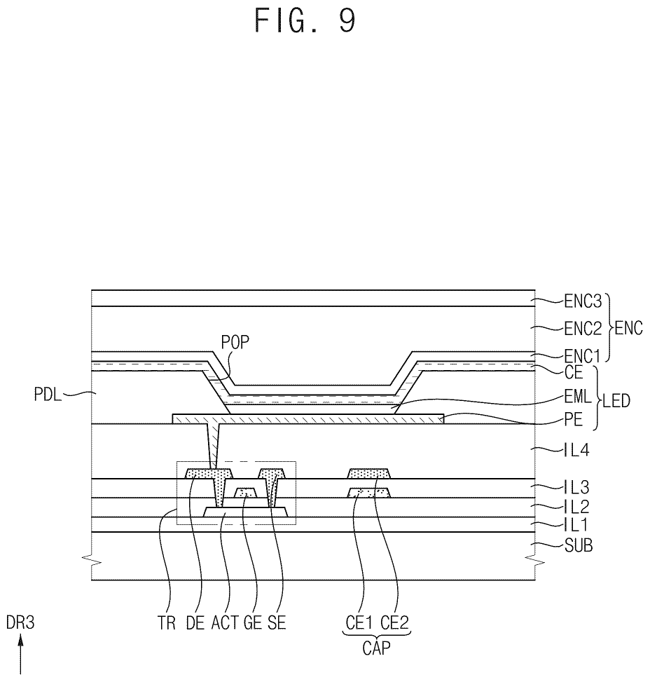

Referring to FIG. 9, the common electrode CE may be formed on the pixel defining layer PDL and the light-emitting layer EML to manufacture the light-emitting element LED. The common electrode CE may be formed entirely in a display area (e.g., the display area DA of FIG. 1).

The encapsulation layer ENC may be formed on the common electrode CE. The encapsulation layer ENC may be formed entirely in the display area. For example, in one or more embodiments, the first inorganic encapsulation layer ENC1, the organic encapsulation layer ENC2, and the second inorganic encapsulation layer ENC3 may be sequentially formed on the common electrode CE.

Referring to FIG. 10, the first touch insulating layer TIL1 may be formed on the second inorganic encapsulation layer ENC3. The first touch insulating layer TIL1 may include an inorganic insulating material.

The first touch electrode TE1 may be formed on the first touch insulating layer TIL1. The first touch electrode TE1 may include the lower conductive layer LCL and the upper conductive layer UCL formed on the lower conductive layer LCL. In one or more embodiments, the lower conductive layer LCL may include a transparent conductive oxide containing indium, and the upper conductive layer UCL may include a metal (e.g., titanium and aluminum).

In one or more embodiments, the etch stop layer ESL may be formed at the same time as the first touch electrode TE1 is formed on the first touch insulating layer TIL1. For example, the etch stop layer ESL may be formed through substantially the same process as the first touch electrode TE1. For example, in one or more embodiments, a metal layer may be formed entirely in the display area on the first touch insulating layer TIL1, and the first touch electrode TE1 and the etch stop layer ESL may be formed by patterning the metal layer.

In one or more embodiments, the etch stop layer ESL may be formed to be around (e.g., surround) the light-emitting layer EML in the plan view.

The etch stop layer ESL may include a lower etch stop layer LCL_E and an upper etch stop layer UCL_E formed on the lower etch stop layer LCL_E. In one or more embodiments, the lower etch stop layer LCL_E may include the same material as the lower conductive layer LCL, and the upper etch stop layer UCL_E may include the same material as the upper conductive layer UCL.

For example, in one or more embodiments, the lower etch stop layer LCL_E may include a transparent conductive oxide containing indium and may have a single-layer structure or a multi-layer structure. The upper etch stop layer UCL_E may include a metal (e.g., titanium and aluminum) and may have a single-layer structure or a multi-layer structure.

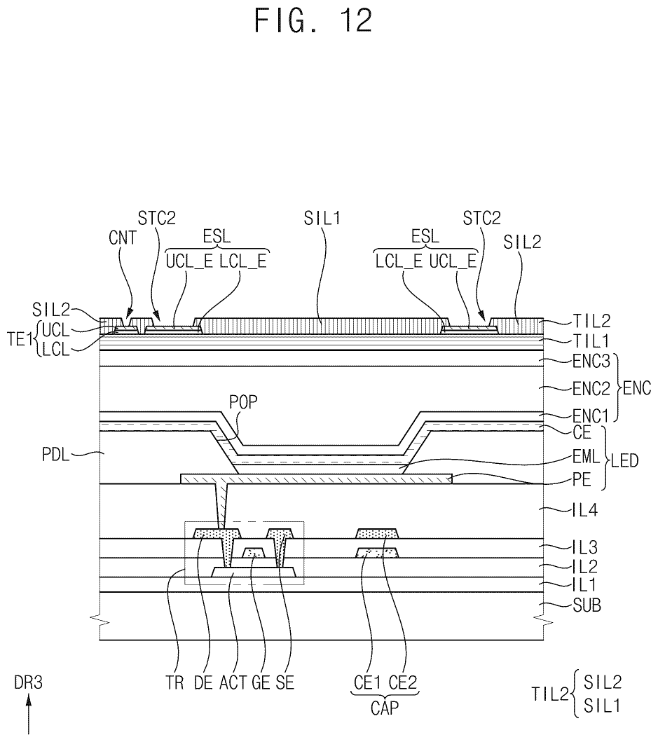

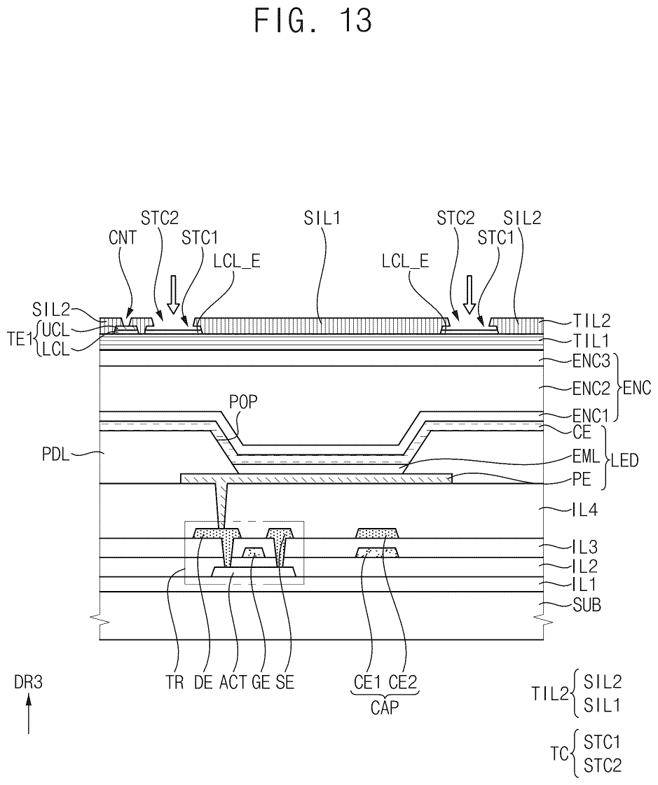

Referring to FIG. 11 and FIG. 12, a preliminary second touch insulating layer TIL2_P covering the first touch electrode TE1 and the etch stop layer ESL may be formed on the first touch insulating layer TIL1. For example, the second preliminary touch insulating layer TIL2_P may include an inorganic insulating material.

A portion of the preliminary second touch insulating layer TIL2_P may be removed through an etching process. Accordingly, the second touch insulating layer TIL2 in which a contact hole CNT exposing at least a portion of the first touch electrode TE1 and the second sub-trench STC2 exposing at least a portion of the etch stop layer ESL are formed (or defined) may be formed. For example, in one or more embodiments, the contact hole CNT and the second sub-trench STC2 may be formed together, e.g., through the same etching process. In one or more embodiments, the contact hole CNT and the second sub-trench STC2 may be formed through separate processes.

At this time, the second touch insulating layer TIL2 may include the first portion SIL1 overlapping the light-emitting layer EML and the second portion SIL2 spaced and/or apart (e.g., spaced apart or separated) from the first portion SIL1 with the etch stop layer ESL therebetween.

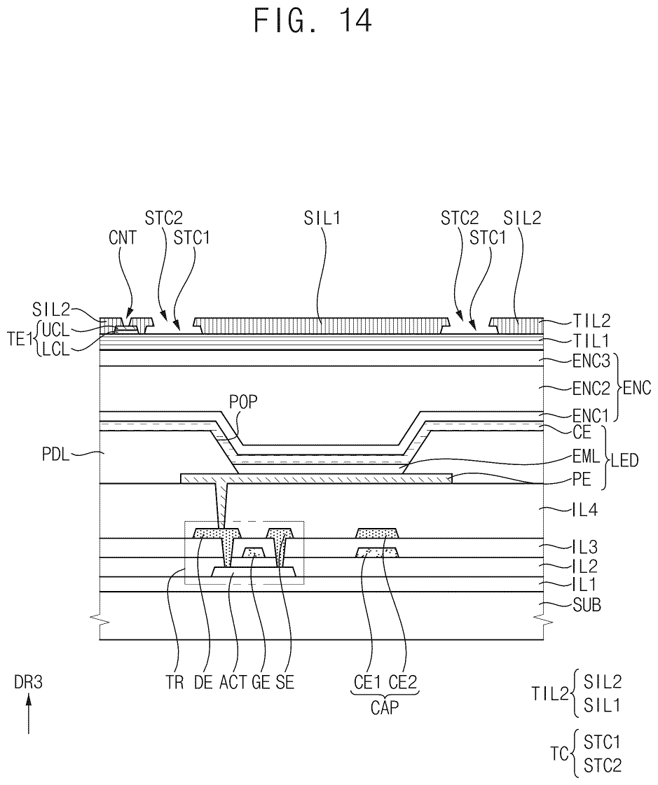

Referring further to FIG. 13, in one or more embodiments, the upper etch stop layer UCL_E of the etch stop layer ESL may be removed through a first etching process. For example, the first etching process may be a dry etch process. However, embodiments of the present disclosure are not necessarily limited thereto.

As the upper etch stop layer UCL_E is removed through the first etching process, the first sub-trench STC1 exposing at least a portion of the lower etch stop layer LCL_E between the lower etch stop layer LCL_E and the second sub-trench STC2 may be formed (or defined) in the second touch insulating layer TIL2.

In one or more embodiments, after the first etching process, some layers (e.g., a layer containing titanium) of the upper etch stop layer UCL_E may remain without being removed. However, embodiments of the present disclosure are not necessarily limited thereto.

In one or more embodiments, in the first etching process, the etch rate of the upper etch stop layer UCL_E may be greater than the etch rate of the lower etch stop layer LCL_E. For example, the etch rate of the upper etch stop layer UCL_E may be greater than the etch rate of the lower etch stop layer LCL_E for the same etchant (e.g., the etchant of the first etching process). Accordingly, after the first etching process, the lower etch stop layer LCL_E may remain without being removed.

Referring further to FIG. 14, in one or more embodiments, the lower etch stop layer LCL_E of the etch stop layer ESL may be removed through a second etching process. For example, the second etching process may be wet etching. However, embodiments of the present disclosure are not necessarily limited thereto.

As the lower etch stop layer LCL_E is removed through the second etching process, the space of the first sub-trench STC1 is expanded so that the second touch insulating layer TIL2 may expose at least a portion of the first touch insulating layer TIL1. For example, the first sub-trench STC1 may be formed in the space where the etch stop layer ESL is removed. Accordingly, the trench TC including the first sub-trench STC1 and the second sub-trench STC2 may be formed in the second touch insulating layer TIL2 in the area where the etch stop layer ESL is removed, and the second touch insulating layer TIL2 may have an undercut shape (e.g., the undercut shape UC of FIG. 6) by the trench TC.

After the second etching process, the first portion SIL1 of the second touch insulating layer TIL2 may be spaced and/or apart (e.g., spaced apart or separated) from the second portion SIL2 with the trench TC therebetween.

In one or more embodiments, in the second etching process, the etch rate of the lower etch stop layer LCL_E may be greater than the etch rate of the first touch insulating layer TIL1. For example, the etch rate of the lower etch stop layer LCL_E may be greater than the etch rate of the first touch insulating layer TIL1 for the same etchant (e.g., the etchant of the second etching process). Accordingly, after the second etching process, the portion of the first touch insulating layer TIL1 exposed by the trench TC may remain without being removed, and in these embodiments, the second inorganic encapsulation layer ENC3 may not be damaged.

As a result, after the trench TC is formed in the second touch insulating layer TIL2 from the etch stop layer ESL including the lower etch stop layer LCL_E and the upper etch stop layer UCL_E, the portion of the first touch insulating layer TIL1 exposed by the trench TC may have a substantially uniform thickness, and the second inorganic encapsulation layer ENC3 may not be damaged. Accordingly, the pixel shrinkage phenomenon, in which the light-emitting area is reduced due to damage to the second inorganic encapsulation layer ENC3, may be suppressed or reduced.

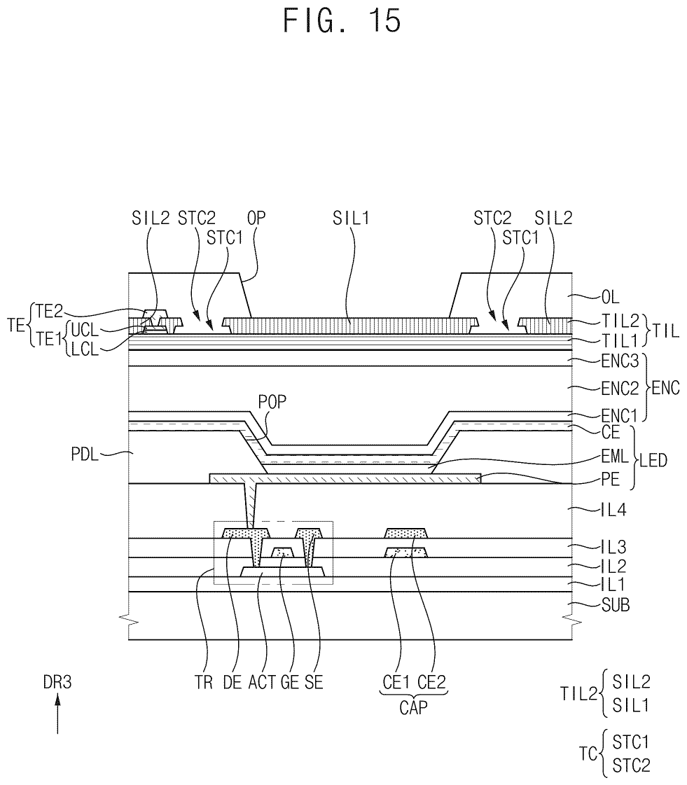

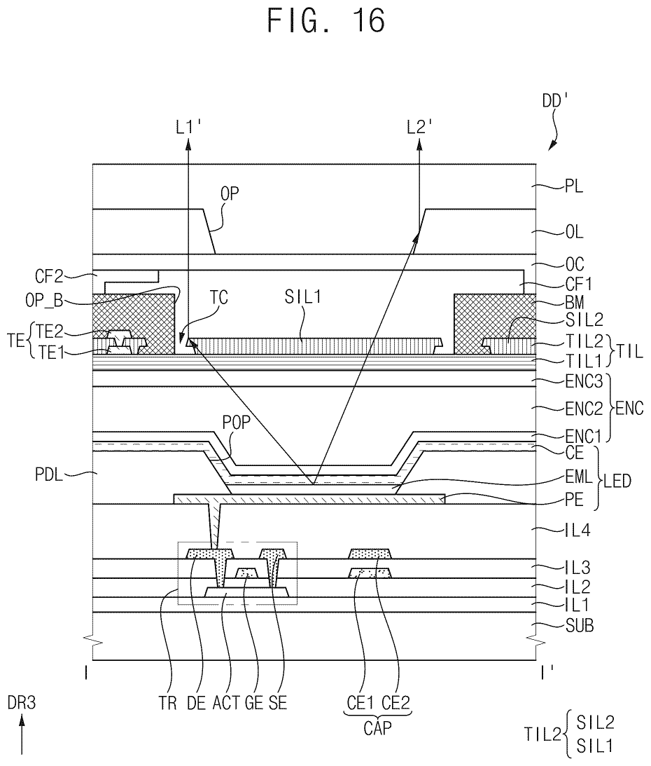

Referring to FIG. 15, the second touch electrode TE2 may be formed on the first touch electrode TE1 and electrically contact with the first touch electrode TE1, and then the organic layer OL may be formed on the second touch insulating layer TIL2. The opening OP may be formed (or defined) in the organic layer OL to overlap the light-emitting layer on a plane and expose at least a portion of the first portion SIL1 of the second touch insulating layer TIL2.

Referring again to FIG. 5, the planarization layer PL may be formed on the organic layer OL. The planarization layer PL may be formed to sufficiently cover the organic layer OL and the first portion SIL1 of the second touch insulating layer TIL2. For example, the planarization layer PL may include an organic insulating material.

Accordingly, the display device DD shown in FIG. 5 may be manufactured.

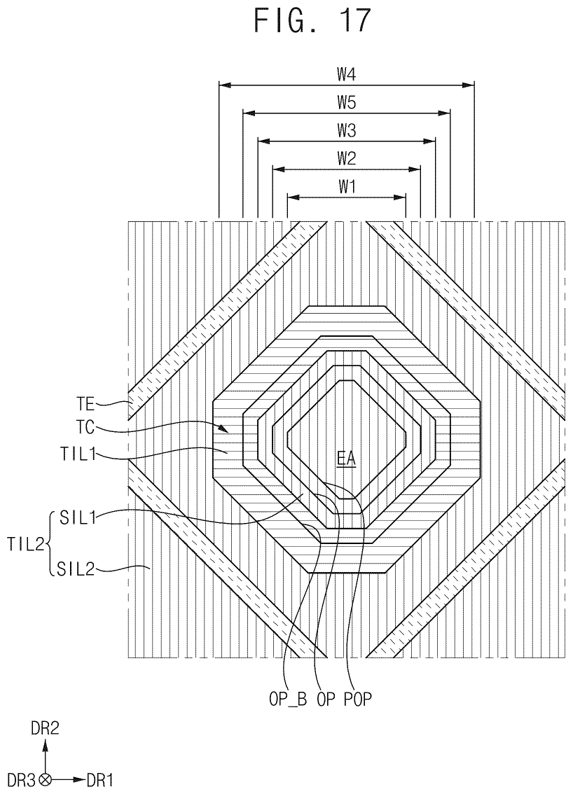

FIG. 16 is a cross-sectional view showing a display device according to one or more embodiments of the present disclosure. FIG. 17 is a plan view showing the display device of FIG. 16.

Referring to FIG. 16 and FIG. 17, a display device DD′ according to one or more embodiments of the present disclosure may include a substrate SUB, a transistor TR, a capacitor CAP, first, second, third, and fourth insulating layers IL1, IL2, IL3, and IL4, a light-emitting element LED, a pixel defining layer PDL, an encapsulation layer ENC, a touch structure, first and second color filters CF1 and CF2, a light blocking layer BM, an overcoat layer OC, an organic layer OL, and a planarization layer PL. Here, the display device DD′ described with reference to FIG. 16 and FIG. 17 may be substantially the same as or similar to the display device DD described with reference to FIG. 5 and FIG. 6 except that the display device DD′ further includes the first and second color filters CF1 and CF2, the light blocking layer BM, and the overcoat layer OC arranged on the touch structure. Hereinafter, descriptions that overlap with those of the display device DD described with reference to FIG. 5 and FIG. 6 will not be provided or simplified.

The touch structure may include a first touch insulating layer TIL1, a touch electrode TE, and a second touch insulating layer TIL2. The touch electrode TE may include a first touch electrode TE1 and a second touch electrode TE2.

The second touch insulating layer TIL2 may be arranged (or located) on the first touch insulating layer TIL1. In one or more embodiments, a trench TC may be defined in the second touch insulating layer TIL2 to be entirely around (e.g., surround) the light-emitting area EA (i.e., the light-emitting layer EML) in a plan view. In addition, the second touch insulating layer TIL2 may include a first portion SIL1 overlapping the light-emitting area EA (i.e., the light-emitting layer EML) and a second portion SIL2 spaced and/or apart (e.g., spaced apart or separated) from the first portion SIL1 with the trench TC therebetween.

The light blocking layer BM may be arranged (or located) on the second touch insulating layer TIL2. The light blocking layer BM may cover the touch electrode TE. An opening OP_B may be defined in the light blocking layer BM. The opening OP_B of the light blocking layer BM may overlap the light-emitting area EA (i.e., the light-emitting layer EML), the pixel opening POP, and the first portion SIL1 of the second touch insulating layer TIL2 in the plan view. In FIG. 16, the opening OP_B may expose at least a portion of the second touch insulating layer TIL2. For example, in one or more embodiments, the light blocking layer BM may include a black matrix.

For example, in one or more embodiments, a width W5 of the opening OP_B may be greater than a width W3 of the first portion SIL1 of the second touch insulating layer TIL2. The light blocking layer BM may entirely cover the second portion SIL2 and may cover a portion of the trench TC. The light blocking layer BM may be directly contact first and second side surfaces (e.g., the first and second side surfaces S12 and S22 of FIG. 6) of the second portion SIL2 defining the trench TC. In addition, the light blocking layer BM may directly contact an upper surface of the first touch insulating layer TIL1 through the trench TC. In these embodiments, the light blocking layer BM may not contact the first and second side surfaces (e.g., the first and second side surfaces S11 and S21 of FIG. 6) of the first portion SIL1 defining the trench TC.

The first color filter CF1 may be arranged (or located) inside the opening OP_B of the light blocking layer BM, and the second color filter CF2 partially overlapping the first color filter CF1 may be arranged (or located) on the light blocking layer BM. The first color filter CF1 may directly contact first and second side surfaces of the first portion SIL1. In addition, the first color filter CF1 may directly contact the first touch insulating layer TIL1 through the trench TC.

The first and second color filters CF1 and CF2 may each have a refractive index smaller than the first refractive index of the touch insulating layer TIL. For example, in one or more embodiments, the first and second color filters CF1 and CF2 may each have a refractive index of about 1.5. However, embodiments of the present disclosure are not necessarily limited thereto.

For example, the first color filter CF1 and the second color filter CF2 may be color filters of different colors. If (e.g., when) the light-emitting layer EML emits red light, the first color filter CF1 may be a red color filter, if (e.g., when) the light-emitting layer EML emits green light, the first color filter CF1 may be a green color filter, and if (e.g., when) the light-emitting layer EML emits blue light, the first color filter CF1 may be a blue color filter.

The overcoat layer OC may be arranged (or located) on the first and second color filters CF1 and CF2. The overcoat layer OC may have a substantially flat upper surface. For example, in one or more embodiments, the overcoat layer OC may include an organic insulating material such as an acrylic resin.

The display device DD′ may prevent or reduce reflection of external light from the outside through the light blocking layer BM, the first and second color filters CF1 and CF2, and the overcoat layer OC. In these embodiments, the display device DD′ including the light blocking layer BM, the first and second color filters CF1 and CF2, and the overcoat layer OC may not include (e.g., may exclude) a separate polarizer.

The organic layer OL may be arranged (or located) on the overcoat layer OC. The opening OP may be defined in the organic layer OL. The opening OP may overlap the light-emitting area EA (i.e., the light-emitting layer EML), the pixel opening POP, and the first portion SIL1 of the second touch insulating layer TIL2 in the plan view. The opening OP may expose at least a portion of the overcoat layer OC. The refractive index of the organic layer OL is the same as described with reference to FIG. 5.

For example, in one or more embodiments, a width W2 of the opening OP may be greater than a width W1 of the pixel opening POP. In one or more embodiments, the width W2 of the opening OP may be substantially same as the width W1 of the pixel opening POP. In one or more embodiments, the width W2 of the opening OP may be smaller than the width W3 of the first portion SIL1. In one or more embodiments, the width W2 of the opening OP may be substantially same as the width W3 of the first portion SIL1. However, embodiments of the present disclosure are not necessarily limited thereto.

For example, in one or more embodiments, the width W2 of the opening OP of the organic layer OL may be smaller than the width W5 of the opening OP_B of the light blocking layer BM. In one or more embodiments, the width W2 of the opening OP of the organic layer OL may be substantially same as the width W5 of the opening OP_B of the light-blocking layer BM. In one or more embodiments, the width W2 of the opening OP of the organic layer OL may be greater than the width of the opening OP_B of the light-blocking layer BM. However, embodiments of the present disclosure are not necessarily limited thereto.

The planarization layer PL may be arranged (or located) on the organic layer OL. The planarization layer PL may have a substantially flat upper surface. The planarization layer PL may fill the opening OP. The planarization layer PL may directly contact an upper surface of the overcoat layer OC through the opening OP. The refractive index of the planarization layer PL is the same as that described with reference to FIG. 5.

A first light L1′ among light emitted from the light-emitting layer EML may travel in a direction oblique to the third direction DR3, be refracted due to the difference in refractive index between the first portion SIL1 and the first color filter CF1, and then travel in the third direction DR3. In addition, a second light L2′ among the light emitted from the light-emitting layer EML may travel in a direction oblique to the third direction DR3 and then be refracted at the side surface of the organic layer OL defining the opening OP and then travel in the third direction DR3.

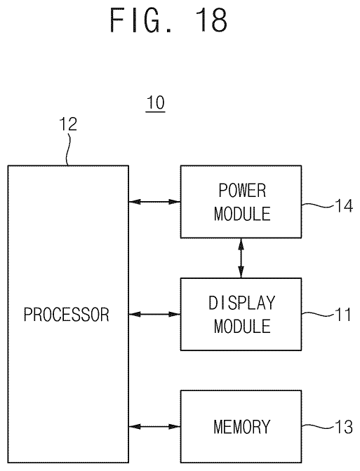

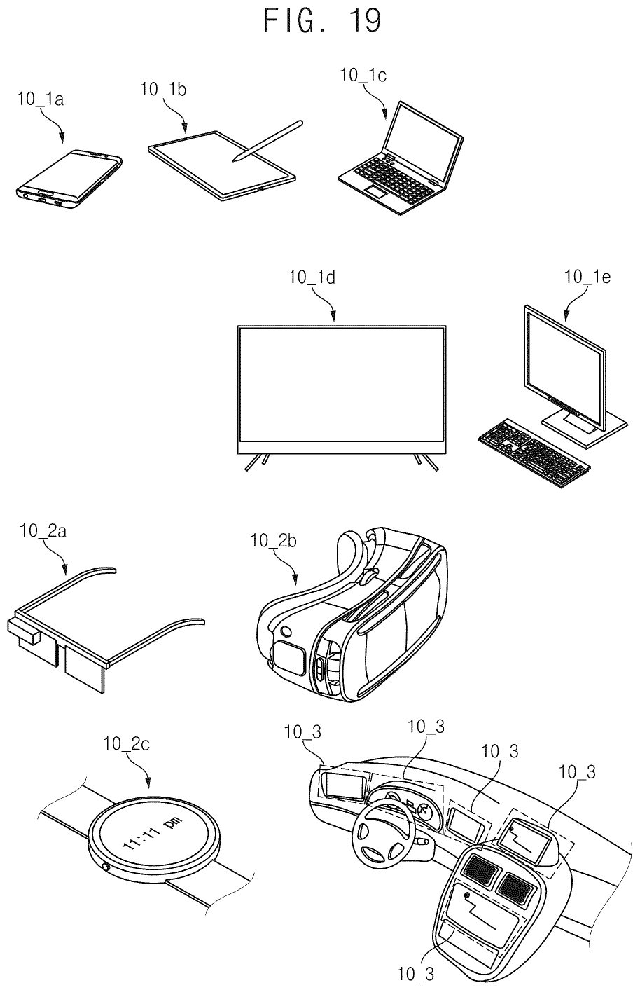

FIG. 18 is a block diagram showing an electronic device according to one or more embodiments of the present disclosure.

Referring to FIG. 18, an electronic device 10 may include a display module 11, a processor 12, a memory 13, and a power module 14.

A display device (e.g., the display device DD of FIG. 1 and FIG. 5 or the display device DD′ of FIG. 16) according to one or more embodiments may be applied to one or more suitable electronic devices 10. The electronic device 10 may include the display device described herein, and may further include modules or devices with additional functions other than the display device.

The processor 12 may include at least one of a central processing unit (CPU), an application processor (AP), a graphic processing unit (GPU), a communication processor (CP), an image signal processor (ISP), or a controller. The processor 12 may control the display device.

The memory 13 may store data information necessary for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module which converts the power supplied by the power supply module to generate power desired or required for the operation of the electronic device 10.

At least one of components of the electronic device 10 described above may be included in the display device according to the above-described embodiments. For example, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

FIG. 19 illustrates schematic diagrams each showing an electronic device according to one or more suitable embodiments of the present disclosure.

Referring to FIG. 19, one or more suitable electronic devices 10 to which display devices (e.g., the display device DD of FIG. 1 and FIG. 5 or the display device DD′ of FIG. 16) according to one or more embodiments are applied may include not only image display electronic devices such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (CID) arranged on a dashboard, and a room mirror display thereof, and/or the like.

The embodiments of the present disclosure may be applied to one or more suitable display devices (in electronic devices). For example, the embodiments of the present disclosure are applicable to one or more suitable display devices such as display devices for vehicles, ships, and aircraft, portable communication devices, display devices for exhibition or information transmission, medical display devices, and/or the like.

In the context of the present application and unless otherwise defined, the terms “use,” “using,” and “used” may be considered synonymous with the terms “utilize,” “utilizing,” and “utilized,” respectively.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the present disclosure, an expression that an element such as a layer, a region, a substrate, or a plate is placed “on” another element indicates not only embodiments in which the element is placed “directly on” the other element but also embodiments in which a further element may be interposed between the element and the other element. In contrast, if (e.g., when) an element is referred to as being “directly on” another element, there are no intervening element present therebetween. The terminology used herein is for the purpose of describing specific embodiments and is not intended to limit the disclosure. Throughout the disclosure, unless explicitly described to the contrary, the word “comprise/include/has” and variations such as “comprises/includes/have” or “comprising/including/having” will be understood to imply the inclusion of stated elements but not the exclusion of any other elements. “At least any one of A, B, and C,” “at least any one of A, B, or C,” “at least any one selected from among A, B, and C,” and “at least any one selected from the group consisting of A, B, and C” may be construed as each of A, B, and C or a (e.g., any suitable) combination of two or more of A, B, and C (for example, ABC, ABB, BC, and CC). As used herein, “and/or” or “or” may include one or more combinations of corresponding components.

It will be understood that, although the terms “first,” “second,” “third,” and so on may be used herein to describe one or more suitable elements, these elements are not limited by these terms. These terms are used to distinguish one element from another element. Thus, a first element described could also be termed as a second or third element without departing from the spirit and scope of the disclosure. As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure.

Spatially relative terms, such as “beneath,” “below,” “lower,” “above,” “upper,” and/or the like, may be used herein for descriptive purposes, and, thereby, to describe one element or feature's relationship to another element(s) or feature(s) as shown in the drawings. Spatially relative terms are intended to encompass different orientations of a device in use, operation, and/or manufacture in addition to the orientation depicted in the drawings. For example, if (e.g., when) the device in the drawings is turned upside down, elements described as “below” or “beneath” other elements or features would then be oriented “above” the other elements or features. Thus, in one or more embodiments, the example term “below” may encompass both (e.g., simultaneously) an orientation of above and below directions. Furthermore, the device may be otherwise oriented (e.g., rotated 90 degrees or at other orientations), and, as such, the spatially relative descriptors used herein interpreted accordingly.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The display device, the electronic device/apparatus, the display device-manufacturing apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The foregoing is illustrative of example embodiments and is not to be construed as limiting thereof. Although a few embodiments have been described, those skilled in the art will readily appreciate that many modifications are possible in one or more embodiments without materially departing from the teachings and advantages of the present disclosure. Accordingly, all such modifications are intended to be included within the scope of the present disclosure as defined in the claims. Therefore, it is to be understood that the foregoing is illustrative of one or more suitable embodiments and is not to be construed as limited to the specific embodiments disclosed, and that modifications to the disclosed embodiments, as well as one or more embodiments, are intended to be included within the scope of the appended claims and equivalents thereof.

What is claimed is:

1. A display device comprising:
a light-emitting element comprising a pixel electrode, a light-emitting layer, and a common electrode sequentially on a substrate;
an encapsulation layer on the light-emitting element;
a first touch insulating layer on the encapsulation layer;
a first touch electrode on the first touch insulating layer;
a second touch insulating layer covering the first touch electrode on the first touch insulating layer, comprising a first portion overlapping the light-emitting layer in a plan view and a second portion spaced from the first portion with a trench therebetween and having an undercut shape by the trench;
an organic layer on the second touch insulating layer and defining an opening overlapping the light-emitting layer in the plan view; and
a planarization layer on the organic layer.

2. The display device of claim 1, wherein the trench comprises:
a first sub-trench exposing at least a portion of the first touch insulating layer and having a first width; and
a second sub-trench exposing the first sub-trench and having a second width smaller than the first width.

3. The display device of claim 2, wherein a first side surface of each of the first and second portions of the second touch insulating layer defining the first sub-trench has an inverse tapered shape, and
a second side surface of each of the first and second portions of the second touch insulating layer defining the second sub-trench has a tapered shape.

4. The display device of claim 2, further comprising:
a residual metal layer located under a protrusion portion comprised in the second touch insulating layer, the protrusion portion protruding toward a center of the trench.

5. The display device of claim 1, wherein the first touch electrode comprises:
a lower conductive layer comprising a transparent conductive oxide containing indium (In); and
an upper conductive layer on the lower conductive layer and comprising a metal.

6. The display device of claim 5, wherein an etch rate of the upper conductive layer is greater than an etch rate of the lower conductive layer for a same etchant, and
the etch rate of the lower conductive layer is greater than an etch rate of the first touch insulating layer for a same etchant.

7. The display device of claim 1, wherein a portion of the first touch insulating layer exposed by the trench has a substantially flat upper surface.

8. The display device of claim 1, further comprising:
a second touch electrode on the second touch insulating layer and connected to the first touch electrode through a contact hole penetrating the second touch insulating layer.

9. The display device of claim 1, wherein each of the first touch insulating layer and the second touch insulating layer has a first refractive index, the organic layer has a second refractive index smaller than the first refractive index, the planarization layer has a third refractive index smaller than the first refractive index, and the third refractive index is greater than the second refractive index.

10. The display device of claim 1, wherein the organic layer entirely covers the trench and directly contacts an upper surface of the first touch insulating layer through the trench.

11. The display device of claim 1, further comprising:
a light-blocking layer on the second touch insulating layer and defining an opening overlapping the light-emitting layer in the plan view;
a color filter layer on the second touch insulating layer and the light-blocking layer; and
an overcoat layer between the color filter layer and the organic layer,
wherein the light-blocking layer covers at least a portion of the trench and directly contacts an upper surface of the first touch insulating layer through the trench.

12. A method, comprising:
forming a light-emitting element comprising a pixel electrode, a light-emitting layer, and a common electrode on a substrate;
forming an encapsulation layer on the light-emitting element;
forming a first touch insulating layer on the encapsulation layer;
forming a first touch electrode comprising a lower conductive layer containing a transparent conductive oxide and an upper conductive layer comprising a metal on the lower conductive layer, while concurrently forming an etch stop layer comprising a lower etch stop layer comprising a same material as the lower conductive layer and an upper etch stop layer comprising a same material as the upper conductive layer on the lower etch stop layer on the first touch insulating layer;
forming a preliminary second touch insulating layer covering the first touch electrode and the etch stop layer on the first touch insulating layer;
forming a second touch insulating layer exposing at least a portion of each of the first touch electrode and the upper etch stop layer by removing a portion of the preliminary second touch insulating layer;
removing the upper etch stop layer through a first etching process;
removing the lower etch stop layer through a second etching process;
forming an organic layer defined an opening overlapping the light-emitting layer in a plan view on the second touch insulating layer; and
forming a planarization layer on the organic layer,
wherein the method is a method for manufacturing a display device.

13. The method of claim 12, wherein in the first etching process, an etch rate of the upper etch stop layer is greater than an etch rate of the lower etch stop layer.

14. The method of claim 12, wherein in the second etching process, an etch rate of the lower etch stop layer is greater than an etch rate of the first touch insulating layer.

15. The method of claim 12, wherein the first etching process is a dry etching process, and the second etching process is a wet etching process.

16. The method of claim 12, wherein each of the lower conductive layer and the lower etch stop layer comprises a transparent conductive oxide containing indium.

17. The method of claim 12, wherein the second touch insulating layer comprises a first portion overlapping the light-emitting layer in the plan view and a second portion spaced from the first portion with the etch stop layer therebetween, and
after the removing the lower etch stop layer, a trench is formed in the second touch insulating layer exposing at least a portion of the first touch insulating layer in an area where the etch stop layer is removed, and the second touch insulating layer has an undercut shape by the trench.

18. The method of claim 17, wherein after the forming the second touch insulating layer, a second sub-trench exposing at least a portion of the lower etch stop layer and having a second width is formed in the second touch insulating layer,
after the removing the lower etch stop layer, a first sub-trench exposing at least a portion of the first touch insulating layer, having a first width greater the second width, and exposed by the second sub-trench is formed in the second touch insulating layer, and
the trench comprises the first sub-trench and the second sub-trench.

19. The method of claim 18, wherein the first sub-trench is formed in a space where the etch stop layer is removed.

20. An electronic device comprising:
a display device; and
a processor which transfers image data signal and input control signal to the display device,
wherein the display device comprises:
a light-emitting element comprising a pixel electrode, a light-emitting layer, and a common electrode sequentially on a substrate;
an encapsulation layer on the light-emitting element;
a first touch insulating layer on the encapsulation layer;
a first touch electrode on the first touch insulating layer;
a second touch insulating layer covering the first touch electrode on the first touch insulating layer, comprising a first portion overlapping the light-emitting layer in a plan view and a second portion spaced from the first portion with a trench therebetween, and having an undercut shape by the trench;
an organic layer on the second touch insulating layer and defining an opening overlapping the light-emitting layer in the plan view; and
a planarization layer on the organic layer.
